(19) United States
(12) Patent Application Publication
(10) Pub. No.: US 2026/0247532 A1
(43) Pub. Date: Aug. 20, 2026

(54) Printed Circuit Board Module, Power Electronic Device and Method for Assembling the Power Electronic Device

(71) Applicant: Siemens Aktiengesellschaft, München (DE)

(72) Inventors: Bin Yang, Nanjing (CN); Bao Lin Li, Nanjing (CN); Jin Kang Wen, Nanjing (CN); Jing Yi Xue, Nanjing (CN); Jing Yi Xue, Nanjing (CN); Christian Frana, Cadolzburg (DE); Alexander Roppelt, Eggolsheim (DE); Jonas Honig, Nürnberg (DE)

(73) Assignee: Siemens Aktiengesellschaft, München (DE)

(21) Appl. No.: 19/161,478

(22) PCT Filed: Mar. 2, 2023
(86) PCT No.: PCT/CN2023/079390

§ 371 Date: Sep. 2, 2025

(51) Int. Cl. H05K 1/14

(52) U.S. Cl. CPC H05K 1/14; H05K 2201/044

(57) ABSTRACT

Some embodiments of the teachings herein include a PCB module. An example comprises: a PCB support plate configured to for vertical assembly with a base plate via slot-column structure, wherein the base plate is assembled in a power electronic device; and a PCB configured to be assembled on the PCB support plate.

### CROSS-REFERENCE TO RELATED APPLICATIONS

This application is a U.S. National Stage Application of International Application No. PCT/CN2023/079390 filed Mar. 2, 2023, which designates the United States of America, the contents of which are hereby incorporated by reference in their entirety.

### TECHNICAL FIELD

The present disclosure relates to electronics. Various embodiments of the teachings herein include printed circuit board (PCB) modules, power electronic devices, and/or methods for assembling power electronic devices.

### BACKGROUND

In order to increase the internal space in a power electronic device such as a frequency converter or a driver for placing more parts, it has become a more and more common technical solution to assemble a PCB laterally, wherein the PCB is electrically connected with another PCB through flexible wire, and another PCB is horizontally assembled on a tray. However, due to the limited space, it is very difficult to fix the PCB with screws from the vertical direction. Generally, the PCB is guided and restricted with slots, or the PCB is fixed with screws from the side. However, due to the insufficient stiffness of the PCB and preventing the damage of components on the PCB in the assembly process, the PCB can only be assembled slowly by manual processes, and cannot be assembled automatically; the efficiency is relatively low. At the same time, in the case of lateral assembly of screws, for the screw assembly direction is perpendicular to the PCB assembly direction, the product needs to be turned during automatically assembly, which leads to low efficiency. The assembly sequence is to install the PCB on the tray first and then the housing.

Therefore, those skilled in the art are also committed to finding other PCB assembly solutions.

### SUMMARY

Some examples of embodiments of the teachings herein include PCB modules, power electronic devices, and/or methods for assembling the power electronic device to achieve PCB automatically assembly.

For example, some embodiments include a PCB module comprising: a PCB support plate, configured to be assembled with a base plate via slot-column structure, wherein the base plate is assembled in a power electronic device; and a PCB, configured to be assembled on the PCB support plate.

As another example, some embodiments include a power electronic device comprising: a base plate and a PCB module, and the PCB module includes: a PCB support plate, configured to be assembled with the base plate via slot-column structure; and a PCB, configured to be assembled on the PCB support plate.

As another example, some embodiments include a method for assembling the power electronic device comprising: pre-assembling a PCB on a PCB support plate to form a PCB module; assembling the PCB module with a base plate in the power electronic device via slot-column structure.

### BRIEF DESCRIPTION OF THE DRAWINGS

For a better understanding of the present application, reference should be made to the Detailed Description below, in conjunction with the following drawings in which like reference numerals refer to corresponding parts throughout the figures.

FIGS. 1A and 1B are schematic diagrams illustrating partial structure of a power electronic device including a PCB module incorporating teachings of the present disclosure;

FIG. 2 is a schematic diagram illustrating the PCB module in FIGS. 1A and 1B;

FIGS. 3A to 3C are schematic diagrams illustrating the PCB support plate in FIG. 2, wherein FIG. 3A is the front view, FIG. 3B is the bottom view, and FIG. 3C is the partial enlarged view of area A in FIG. 3B;

FIGS. 4A and 4B are schematic diagrams illustrating the base plate in FIGS. 1A and 1B, wherein FIG. 4A is the front view, and FIG. 4B is the detailed view of area B in FIG. 4A;

FIGS. 5A and 5B are schematic diagrams illustrating the assembly relationship between the PCB support plate and the base plate, wherein FIG. 5A is the I-I partial cross-sectional view of FIG. 1B, and FIG. 5B is the II-II partial cross-sectional view of FIG. 1B;

FIG. 6 is a schematic diagram illustrating the assembly relationship between the PCB support plate and a tray in FIGS. 1A and 1B;

FIG. 7 is a schematic diagram illustrating the assembly relationship between the PCB and another PCB in FIGS. 1A and 1B;

FIG. 8 is a schematic diagram illustrating an adsorbing location of vacuum suction pads during an assembly process incorporating teachings of the present disclosure; and

FIG. 9 is a flow diagram illustrating a method for using the motor driver shown in FIG. 1 incorporating teachings of the present disclosure.

The reference numerals are as follows:

| Reference numeral | Object |
|---|---|
| 1 | PCB module |
| 11 | PCB |
| 111 | first board-to-board connector |
| 12 | PCB support plate |
| 121 | wedge-shaped slot |
| 122 | snap-fitv |
| 2 | base plate |
| 21 | wedge-shaped column |
| 3 | tray |
| 31 | groove |
| 4 | another PCB |
| 41 | second board-to-board connector |
| 5 | vacuum suction pad |
| 91, 92 | Processes |

### DETAILED DESCRIPTION

In example embodiments of the application, by pre-assembling the PCB on a PCB support plate to form a PCB module, the PCB module may be automatically assembled on a base plate in a power electronic device with slot-column structure, so that the PCB may be assembled efficiently and fully automatically, which can optimize the assembly work from manual operation to automatic assembly, thus the assembly man hours can be saved and the assembly efficiency can be improved. In addition, since the PCB module can be assembled with the base plate via slot-column structure and assembled with the tray via snap-fit structure, the assembly direction of the PCB module is the same as that of other parts of the power electronic device, the turnover of parts in the assembly process can be avoided, thus the assembly efficiency can be further improved.

In order to achieve the automatically assembly of the PCB, a PCB support plate may be provided. The PCB can be assembled on the PCB support plate to form a PCB module, and the PCB support plate can be assembled with a base plate with slot-column structure. In addition, the PCB support plate can be assembled with the tray with snap-fits. Furthermore, the PCB can be equipped with another PCB using board-to-board connectors to achieve the hard connection between PCBs and avoid the flexible wire connection that cannot be assembled automatically.

Reference will now be made in detail to examples, which are illustrated in the accompanying drawings. In the following detailed description, numerous specific details are set forth to provide a thorough understanding of the present application. Also, the figures are illustrations of an example, in which assemblies shown in the figures are not necessarily essential for implementing the teachings of the present disclosure. In other instances, well-known assemblies, components, and circuits have not been described in detail so as not to unnecessarily obscure aspects of the examples.

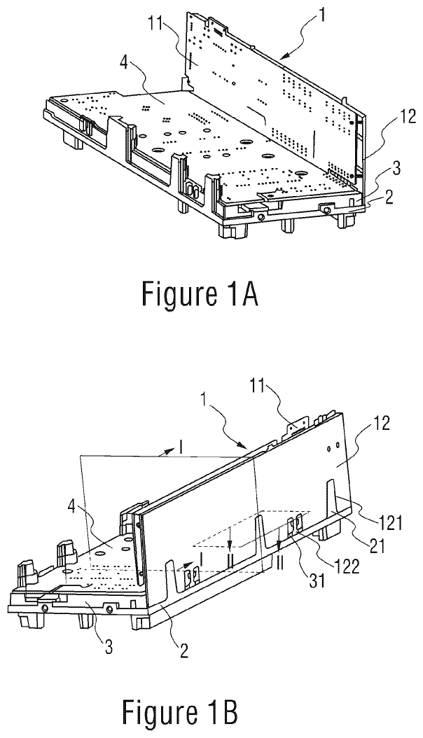

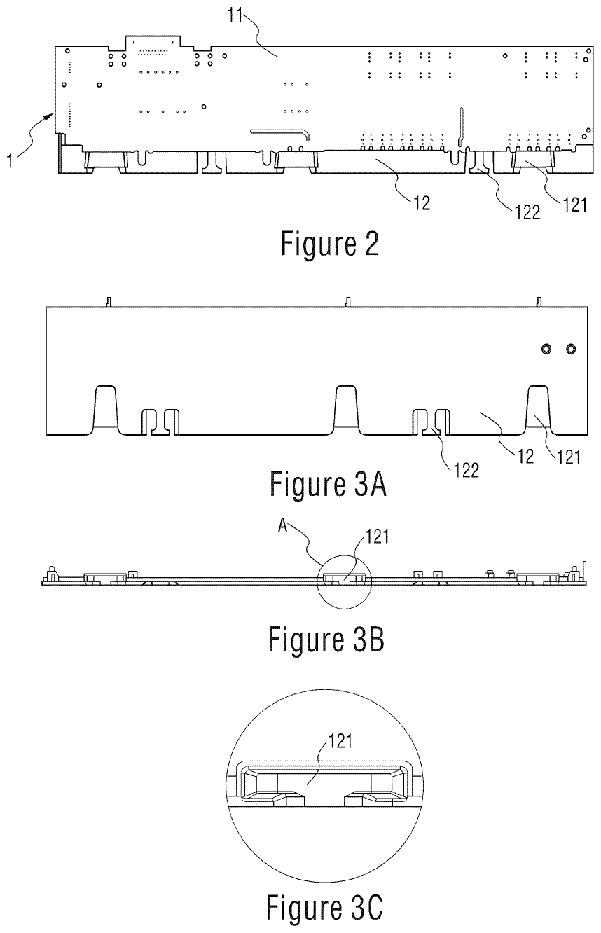

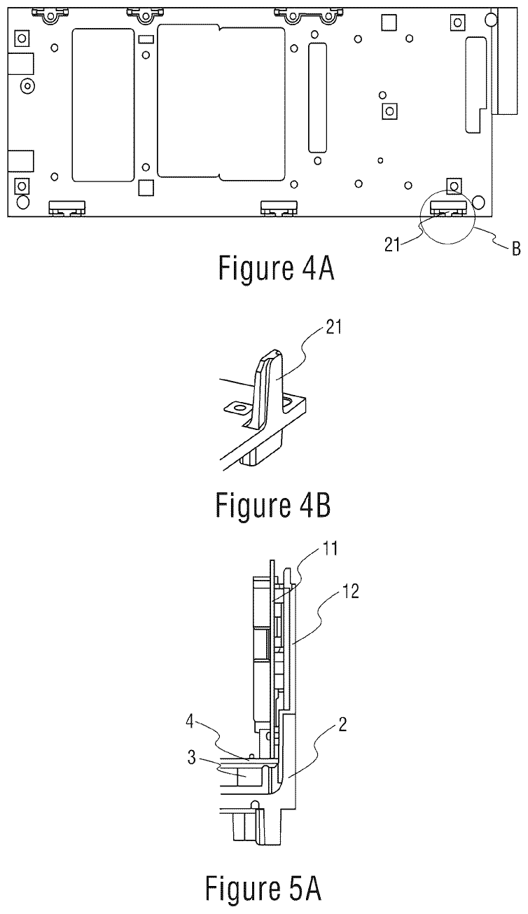

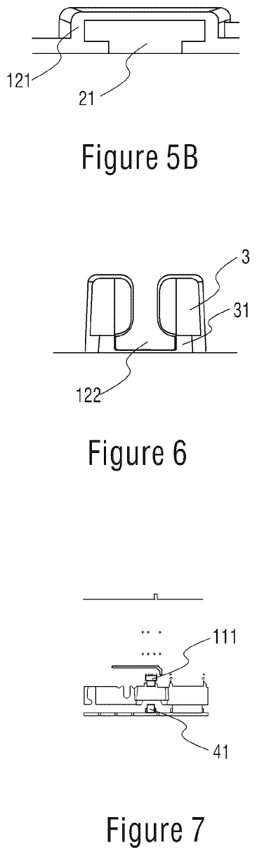

FIGS. 1A and 1B are schematic diagrams illustrating partial structure of a power electronic device including a PCB module incorporating teachings of the present disclosure. FIG. 2 is a schematic diagram illustrating the PCB module in FIGS. 1A and 1B. FIGS. 3A to 3C are schematic diagrams illustrating the PCB support plate in FIG. 2, FIGS. 4A and 4B are schematic diagrams illustrating the base plate in FIGS. 1A and 1B, and FIGS. 5A and 5B are schematic diagrams illustrating the assembly relationship between the PCB support plate and the base plate. FIG. 6 is a schematic diagram illustrating the assembly relationship between the PCB support plate and a tray in FIGS. 1A and 1B. FIG. 7 is a schematic diagram illustrating the assembly relationship between the PCB and another PCB in FIGS. 1A and 1B.

As shown in FIGS. 1A, 1B and 2, the PCB module 1 in the power electronic device includes a PCB 11 and a PCB support plate 12.

The PCB 11 is configured to be pre-assembled with the PCB support plate 12 to form the PCB module 1. The PCB 11 may include a positioning and matching structure.

The PCB support plate 12 is configured to be assembled with a base plate 2 via slot-column structure, wherein the base plate 2 is assembled in the power electronic device. The power electronic device may be a frequency converter, a driver, or the like.

As shown in FIGS. 1B, 2 and 3A to 3B, the PCB support plate 12 includes multiple wedge-shaped slots 121 for example three wedge-shaped slots 121 formed on the side of the PCB support plate 12, and the cross section of each of the wedge-shaped slots 121 is narrow outside and wide inside. Correspondingly, as shown in FIGS. 1B, 4A and 4B, the base plate 2 includes multiple corresponding wedge-shaped columns 21 for example three corresponding wedge-shaped columns 21 formed on the base plate 2, and the cross section of each of the wedge-shaped columns 21 is stepped. As shown in FIGS. 5A and 5B, the semi surrounding of each slot 121 to each corresponding column 21 and the complete restriction of the degree of freedom in the horizontal direction can be achieved, and the wedge-shaped columns 21 may drastically increase the robustness of the overall connection.

In another example, the wedge-shaped slots may be formed on the base plate 2, and the wedge-shaped columns may be correspondingly formed on the PCB support plate 12.

In addition, as shown in FIGS. 1B, 2, 3A to 3B and 6, the PCB support plate 12 may be further configured to be assembled with a tray 3 via snap-fit structure, wherein the tray 3 is assembled on the base plate 2. In the example, the PCB support plate 12 further includes multiple snap-fits 122, which is configured to snap in a groove 31 on the tray 3, and the assembly direction of the snap-fits is the same as that of the PCB, with the snap-fit structure, the full degree of freedom of the PCB module can be constrained. In the example, the snap-fits 122 are disposed on the PCB support plate 12, in another example, the snap-fits may be disposed on the tray 3, and the groove may be correspondingly disposed on the PCB support plate 12.

Furthermore, as shown in FIGS. 1A and 7, the PCB 11 may be further configured to be equipped with another PCB 4 using board-to-board connectors 111/41, namely the PCB 11 includes a first board-to-board connector 111, and another PCB 4 includes a second board-to-board connector 41, so that the hard connection between PCBs can be achieved, and the flexible wire connection that cannot be assembled automatically can be avoided. Another PCB 4 is assembled on the tray 3.

With above mentioned structure, the assembly direction of the PCB module may be same as that of the base plate and other parts, namely the PCB module may be assembled vertically and the turnover of parts in the assembly process can be avoided. Meanwhile, the modular design enables the PCB to be assembled efficiently and automatically, in view of the current situation of labor shortage and long delivery time, which can reduce man-hour labor dependence and shorten delivery time.

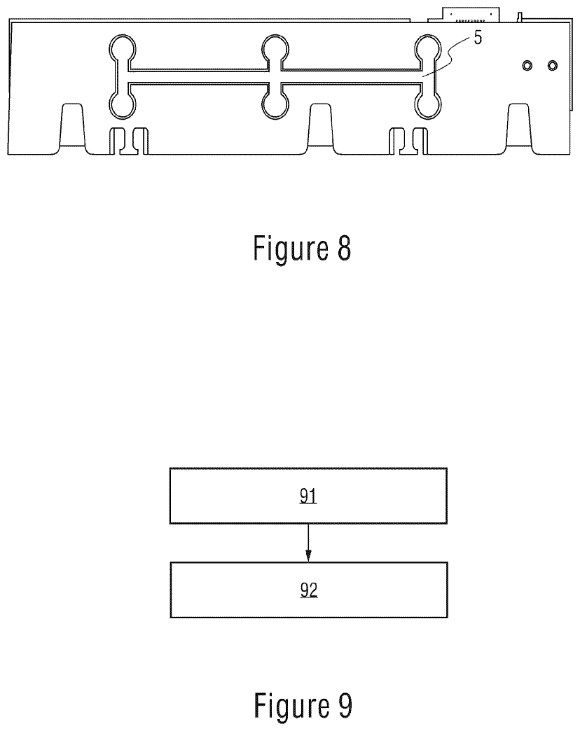

In addition, in automatic assembly process, vacuum suction pads are needed to be adsorbed on the PCB module, in the present application, as shown in FIG. 8, the vacuum suction pads 5 may be adsorbed on the PCB support plate 12, namely, compared with PCB without the PCB support plate, it is not necessary to destroy the area on the PCB, so that more devices can be placed on the PCB, and the potential creepage/clearance issues can be eliminated in advance.

The PCB module and the power electronic device in examples of the present application is described in detail above, and the method for assembling the electronic device in examples of the application is described in detail below.

FIG. 9 is a flow diagram illustrating a method for assembling the power electronic device shown in FIG. 1 incorporating teachings of the present disclosure. As shown in FIG. 9, the method may include the following processes.

At block 91, pre-assembling a PCB on a PCB support plate to form a PCB module.

At block 92, assembling the PCB module with a base plate in the power electronic device via slot-column structure. In the example, the block 92 may further include: assembling the PCB module with a tray assembled on the base plate via snap-fit structure. In addition, the block 92 may further include: equipping the PCB with another PCB assembled on the tray using board-to-board connectors.

It can be seen from the above technical solutions that in embodiments of the teachings herein, by pre-assembling the PCB on a PCB support plate to form a PCB module, the PCB module may be automatically assembled on a base plate in a power electronic device with slot-column structure, so that the PCB may be assembled efficiently and fully automatically, which can optimize the assembly work from manual operation to automatic assembly, thus the assembly man hours can be saved and the assembly efficiency can be improved.

In addition, since the PCB module can be assembled with the base plate via slot-column structure and assembled with the tray via snap-fit structure, the assembly direction of the PCB module is the same as that of other parts of the power electronic device, the turnover of parts in the assembly process can be avoided, thus the assembly efficiency can be further improved.

As used herein, unless the context clearly supports exceptions, the singular forms “a” (“a”, “an”, “the”) are intended to include the plural forms. It should also be understood that, “and/or” used herein is intended to include any and all possible combinations of one or more of the associated listed items.

The embodiments of the present application are only used for description, and do not represent the merits of the implementations. The foregoing description, for purpose of explanation, has been described with reference to specific examples. However, the illustrative discussions above are not intended to be exhaustive or to limit the present application to the precise forms disclosed. Many modifications and variations are possible in view of the above teachings. The examples were chosen and described to best explain the principles of the present application and its practical applications, to thereby enable others skilled in the art to best utilize the present application and various examples with various modifications as are suited to the particular use contemplated.

What is claimed is:

1. A PCB module comprising:
a PCB support plate configured to for vertical assembly with a base plate via slot-column structure, wherein the base plate is assembled in a power electronic device; and
a PCB configured to be assembled on the PCB support plate.

2. The PCB module according to claim 1, wherein:
the PCB support plate is further configured for vertical assembly with a tray via snap-fit structure; and
the tray is assembled on the base plate.

3. The PCB module according to claim 2, wherein the PCB is further configured for connection to another PCB using board-to-board connectors; and
another PCB is assembled on the tray.

4. A power electronic device comprising:
a base plate;
a PCB module comprising
a PCB support plate configured for vertical assembly with the base plate via slot-column structure; and
a PCB configured for assembly on the PCB support plate.

5. The power electronic device according to claim 4, further comprising a tray assembled on the base plate;
wherein the PCB support plate is further configured for vertical assembly with the tray via snap-fit structure.

6. The power electronic device according to claim 5, further comprising another PCB assembled on the tray;
wherein the PCB is connected to the another PCB by board-to-board connectors.

7. The power electronic device according to claim 4, wherein the power electronic device comprises a frequency converter or a driver.

8. A method for assembling a power electronic device, the method comprising:
pre-assembling a PCB on a PCB support plate to form a PCB module;
vertically assembling the PCB module with a base plate in the power electronic device via slot-column structure.

9. The method for assembling the power electronic device according to claim 8, wherein, when vertically assembling the PCB module with the base plate includes assembling the PCB module with a tray assembled on the base plate via snap-fit structure.

10. The method for assembling the power electronic device according to claim 9, wherein vertically assembling the PCB module with the tray includes connecting the PCB to another PCB assembled on the tray using board-to-board connectors.
